(19) United States
(12) Patent Application Publication
(10) Pub. No.: US 2024/0014221 A1
(43) Pub. Date: Jan. 11, 2024

(54) SEMICONDUCTOR PACKAGE AND PACKAGE MODULE INCLUDING THE SAME

(71) Applicant: SAMSUNG ELECTRONICS CO., LTD., SUWON-SI (KR)

(72) Inventor: SOYOUNG LIM, Suwon-si (KR)

(21) Appl. No.: 18/124,118

(22) Filed: Mar. 21, 2023

(30) Foreign Application Priority Data
Jul. 11, 2022 (KR) 10-2022-0085242

(51) Int. Cl. H01L 27/12; G09G 3/20

(52) U.S. Cl. CPC H01L 27/124; G09G 3/2092; G09G 2300/0408; G09G 2300/0426

(57) ABSTRACT

A semiconductor package includes: a film having a first surface and a second surface, which are opposite to each other, and including a first connection region and a second connection region, which are spaced apart from each other; first connection pads disposed on the first connection region; second connection pads disposed on the second connection region; and a semiconductor chip disposed on the first surface and between the first connection region and the second connection region, wherein the semiconductor chip includes: input pads disposed on a first pad region; first output pads disposed on the first pad region; and second output pads disposed on a second pad region spaced apart from the first pad region, and at least one of the first output pads is electrically connected to a corresponding second connection pad of the second connection pads through a first via and a second via penetrating the film.

### CROSS-REFERENCE TO RELATED APPLICATIONS

This U.S. non-provisional patent application claims priority under 35 U.S.C. § 119 to Korean Patent Application No. 10-2022-0085242, filed on Jul. 11, 2022, in the Korean Intellectual Property Office, the disclosure of which is incorporated by reference herein in its entirety.

### TECHNICAL FIELD

The present inventive concept relates to a semiconductor package, and more particularly. to a chip-on-film package and a package module including the same.

### DISCUSSION OF THE RELATED ART

A chip-on-film (COF) packaging technology using a flexible film substrate has been under development to meet technical demands for small-sized, thin, and lightweight electronic products. Generally, in the COF packaging technology, a semiconductor chip is mounted on the film substrate in a flip-chip bonding manner and is coupled to an external circuit through short lead wires. Typically, this COF package is applied to a panel of a portable device (e.g., a cellular phone and a personal digital assistant (PDA)), a laptop computer, or a display device.

### SUMMARY

An embodiment of the present inventive concept provides a semiconductor package of a relatively small size and a package module including the same.

An embodiment of the present inventive concept provides a semiconductor package with a relatively high integration density and a package module including the same.

According to an embodiment of the present inventive concept, a semiconductor package includes: a film having a first surface and a second surface, which are opposite to each other, and including a first connection region and a second connection region, which are spaced apart from each other in a first direction; first connection pads disposed on the first connection region of the film; second connection pads disposed on the second connection region of the film; and a semiconductor chip disposed on the first surface of the film and between the first connection region and the second connection region, wherein the semiconductor chip includes: input pads disposed on a first pad region; first output pads disposed on the first pad region; and second output pads disposed on a second pad region spaced apart from the first pad region, and at least one of the first output pads is electrically connected to a corresponding second connection pad of the second connection pads through a first via and a second via penetrating the film.

According to an embodiment of the present inventive concept, a semiconductor package includes: a film substrate having a first surface and a second surface, which are opposite to each other, wherein the film substrate includes first connection pads, which are provided on the first surface and are spaced apart from each other in a first direction, and second connection pads, which are spaced apart from the first connection pads in a second direction crossing the first direction; a semiconductor chip provided on the first surface and between the first connection pads and the second connection pads; wires connecting the semiconductor chip to the first connection pads and the second connection pads; first vias provided between the semiconductor chip and the first connection pads, wherein the first vias penetrate the film substrate; and second vias provided between the semiconductor chip and the second connection pads, wherein the second vias penetrate the film substrate, wherein the semiconductor chip and the second connection pads are electrically connected to each other through the first vias and the second vias.

According to an embodiment of the present inventive concept, a semiconductor module includes: a circuit substrate; a display device spaced apart from the circuit substrate; and a film package provided between the circuit substrate and the display device and electrically connected, to the circuit substrate and the display device, wherein the film package includes: a film substrate having a first surface and a second surface, which are opposite to each other; a semiconductor chip mounted on a first surface of the film substrate, wherein the semiconductor chip includes a first pad region and a second pad region, wherein the first pad region is adjacent to the circuit substrate, and the second pad region is adjacent to the display device; first connection pads provided on the first surface of the film substrate and between the semiconductor chip and the circuit substrate; second connection pads provided on the first surface of the film substrate and between the semiconductor chip and the display device; wires electrically connecting the semiconductor chip to the first connection pads and to the second connection pads; first vias provided between the semiconductor chip and the first connection pads, wherein the first vias penetrate the film substrate; second vias provided between the semiconductor chip and the second connection pads, wherein the second vias penetrate the film substrate; first output pads provided in the first pad region; second output pads provided in the second pad region; and lower wires provided on the second surface of the film substrate and connecting the first vias to the second vias, wherein at least one of the first output pads is electrically connected to a corresponding second connection pad of the second connection pads through a corresponding lower wire of the lower wires.

### BRIEF DESCRIPTION OF THE DRAWINGS

FIG. 1 is a layout diagram illustrating a semiconductor package according to an embodiment of the present inventive concept.

FIG. 2 is a layout diagram illustrating a back-side shape of a semiconductor package according to an embodiment of the present inventive concept and, for example, illustrating a bottom surface of the semiconductor package of FIG. 1.

FIG. 3 is an enlarged diagram illustrating a portion ‘I’ of FIG. 1.

FIG. 4 is a sectional view, which is taken along a line A-A′ of FIG. 1 to illustrate a semiconductor package according to an embodiment of the present inventive concept.

FIG. 5 is a sectional view, which is taken along a line B-B′ of FIG. 1 to illustrate a semiconductor package according to an embodiment of the present inventive concept.

FIG. 6 is a sectional view, which is taken along a line C-C′ of FIG. 1 to illustrate a semiconductor package according to an embodiment of the present inventive concept.

FIG. 7 is a plan view illustrating an example of chip pads arranged in a semiconductor package according to an embodiment of the present inventive concept.

FIG. 8 is a layout diagram illustrating a semiconductor package according to an embodiment of the present inventive concept.

FIG. 9 is a layout diagram illustrating a back-side shape of a semiconductor package according to an embodiment of the present inventive concept and, for example, illustrating a bottom surface of the semiconductor package of FIG. 8.

FIG. 10 is a layout diagram illustrating a semiconductor package according to an embodiment of the present inventive concept.

FIG. 11 is a layout diagram illustrating a back-side shape of a semiconductor package according to an embodiment of the present inventive concept and, for example, illustrating a bottom surface of the semiconductor package of FIG. 10.

FIG. 12 is a layout diagram illustrating a semiconductor package according to an embodiment of the present inventive concept.

FIG. 13 is a layout diagram illustrating a back-side shape of a semiconductor package according to an embodiment of the present inventive concept and, for example, illustrating a bottom surface of the semiconductor package of FIG. 12.

FIG. 14 is a plan view illustrating a package module according to an embodiment of the present inventive concept.

FIG. 15 is a sectional view, which is taken along a line D-D′ of FIG. 14 to illustrate a package module according to an embodiment of the present inventive concept.

### DETAILED DESCRIPTION OF THE EMBODIMENTS

Embodiments of the present inventive concepts will now be described more fully with reference to the accompanying drawings, in which example embodiments of the present inventive concept are shown, bike reference numerals in the drawings denote like elements, and thus repetitive descriptions will be omitted or briefly described.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

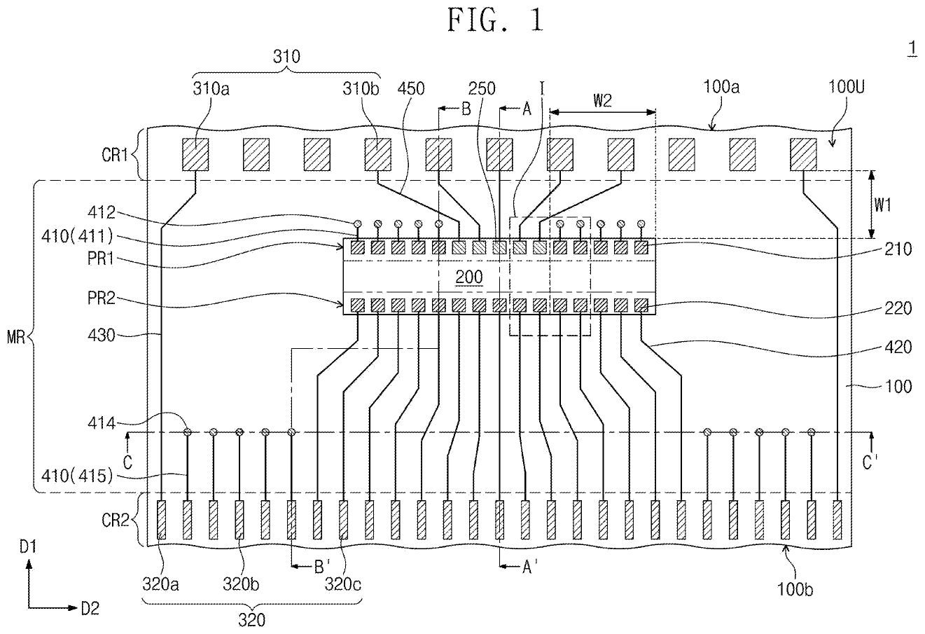

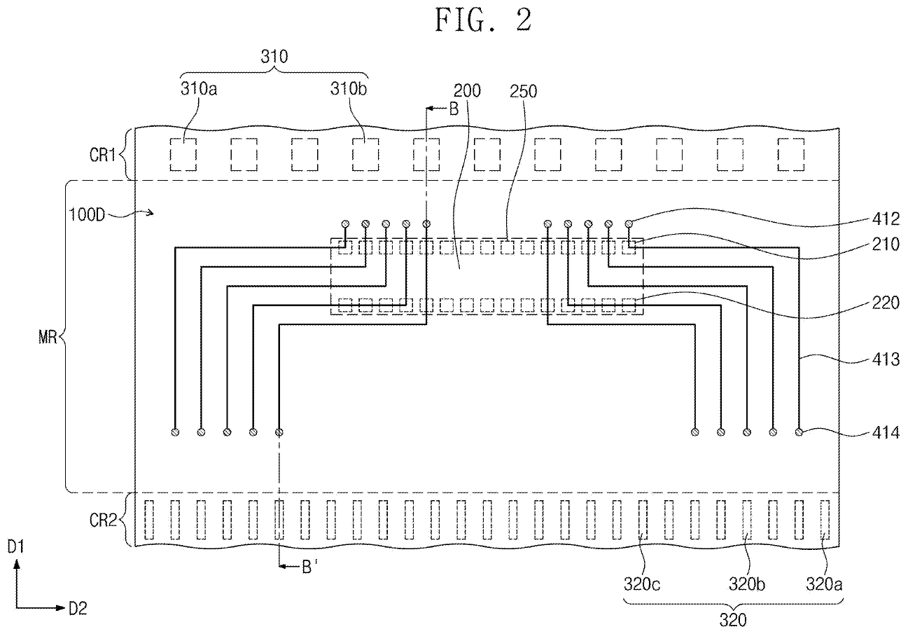

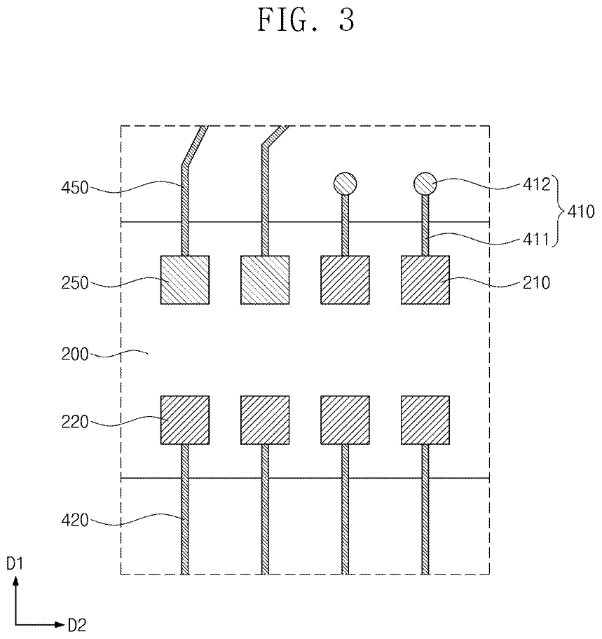

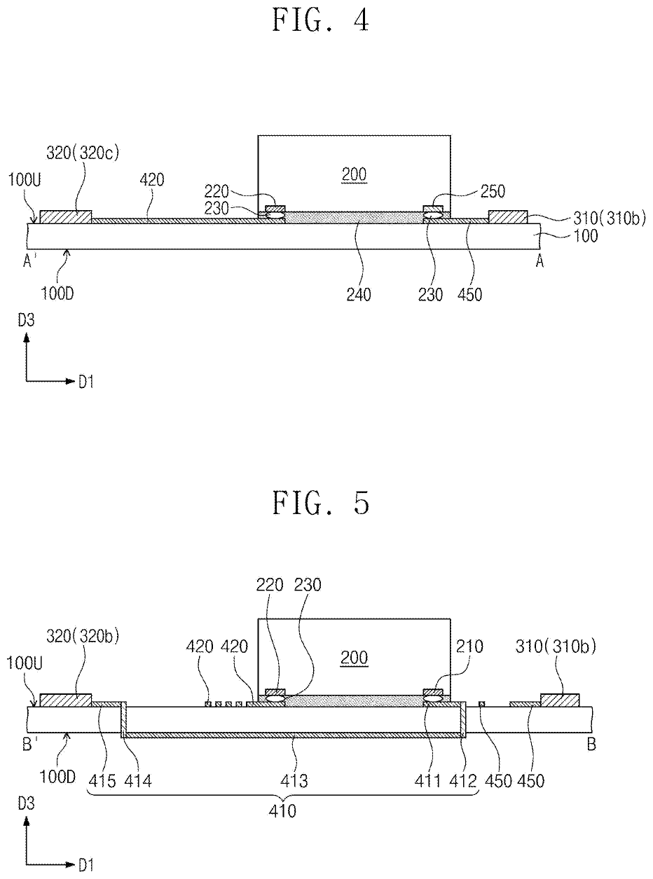

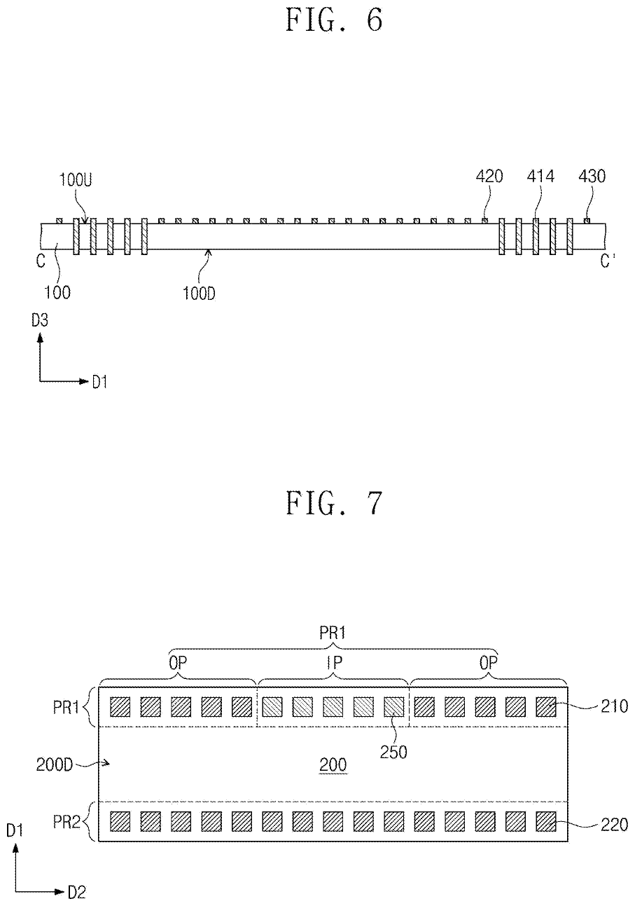

FIG. 1 is a layout diagram illustrating a semiconductor package according to an embodiment of the present inventive concept. FIG. 2 is a layout diagram illustrating a back-side shape of a semiconductor package according to an embodiment of the present inventive concept and, for example, illustrating a bottom surface of the semiconductor package of FIG. 1. FIG. 3 is an enlarged diagram illustrating a portion ‘I’ of FIG. 1. FIG. 4 is a sectional view, which is taken along a line A-A′ of FIG. 1 to illustrate a semiconductor package according to an embodiment of the present inventive concept. FIG. 5 is a sectional view, which is taken along a line B-B′ of FIG. 1 to illustrate a semiconductor package according to an embodiment of the present inventive concept. FIG. 6 is a sectional view, which is taken along a line C-C′ of FIG. 1 to illustrate a semiconductor package according to an embodiment of the present inventive concept. FIG. 7 is a plan view illustrating an example of chip pads arranged in a semiconductor package according to an embodiment of the present inventive concept.

Referring to FIGS. 1 and 2, a semiconductor package 1 may include a film substrate 100, a semiconductor chip 200, first connection pads 310, second connection pads 320, wires 410, 420, and 450, and vias 412 and 414.

The film substrate 100 may be provided. The film substrate 100 may be a base film, on which the semiconductor chip 200, the first connection pads 310, the second connection pads 320, the wires 410, 420, and 450, and the vias 412 and 414 are provided. The film substrate 100 may be extended in a first direction D1, which is parallel to a top surface of the film substrate 100. For example, the film substrate 100 may be formed of or include at least one of polymeric materials (e.g., polyimide). The film substrate 100 may be flexible.

The film substrate 100 may have a first surface 100U and a second surface 100D, which are opposite to each other. For example, the first surface 100U of the film substrate 100 may be a top surface, and the second surface 1001) may be a bottom surface. A first end portion 100a of the film substrate 100 may be an end portion of the film substrate 100 in the first direction D1, and a second end portion 100b of the film substrate 100 may be an end portion of the film substrate 100 in an opposite direction of the first direction D1. The film substrate 100 may include a first connection region CR1, a second connection region CR2, and a mounting region MR. When viewed in a plan view, the first connection region CR1, the mounting region MR, and the second connection region CR2 may be sequentially arranged in the first direction D1. The first connection region CR1, the mounting region MR, and the second connection region CR2 might not be overlapped with each other. The mounting region MR may be disposed between the first and second connection regions CR1 and CR2. The first and second connection regions CR1 and CR2 may be connected to opposite ends (i.e., edge portions) of the film substrate 100. The first connection region CR1 may be connected to the first end portion 100a of the film substrate 100. The second connection region CR2 may be connected to the second end portion 100b of the film substrate 100. The first and second connection regions CR1 and CR2 may be spaced apart from each other in the first direction D1, with the mounting region MR interposed therebetween. A width of the mounting region MR in the first direction D1 may be larger than each of widths of the first and second connection regions CR1 and CR2 in the first direction D1.

The semiconductor chip 200 may be provided on the first surface 100U of the film substrate 100. The semiconductor chip 200 may be provided in the mounting region MR. The semiconductor chip 200 may be disposed on the first surface 100U of the film substrate 100 in a face-down manner. As an example, the semiconductor chip 200 may be disposed such that an active surface thereof faces the first surface 100U of the film substrate 100. The semiconductor chip 200 may be a display driver integrated-circuit (DOI) chip.

Referring to FIG. 7, the semiconductor chip 200 may include a first pad region PR1 and a second pad region PR2 provided on a bottom surface 200D. The first pad region PR1, and the second pad region PR2 may be spaced apart from each other in the first direction D1. The first pad region PR1 and the second pad region PR2 may be disposed at both sides (e.g., opposing sides) or edge regions of the bottom surface 200D of the semiconductor chip 200. The first pad region PR1 may be closer to the first connection region CR1 than the second pad region PR2 is. The second pad region PR2 may be closer to the second connection region CR2 than the first pad region PR1 is.

The first pad region PR1 may include output pad regions OP and an input pad region IP. The output pad regions OP may be disposed at and connected to both sides of the input pad region IP. The output pad regions OP and the input pad region IP may be arranged in a second direction D2. The output pad regions OP and the input pad region IP might not be overlapped with each other, when viewed in a plan view. The output pad regions OP may be spaced apart from each other in the second direction D2, with the input pad region IP interposed therebetween.

Input pads 250 may be provided in the input pad region IP. The input pads 250 may be spaced apart from each other in the second direction D2. First output pads 210 may be provided in the output pad regions OP. The first output pads 210 may be spaced apart from each other in the second direction 132. Second output pads 220 may be provided in the second pad region PR2. The second output pads 220 may be spaced apart from each other in the second direction D2. The input pads 250, the first output pads 210, and the second output pads 220 may be formed of or include at least one of conductive materials. The input pads 250 may be connected to an integrated circuit of the semiconductor chip 200 and may be used to deliver input signals to the integrated circuit of the semiconductor chip 200. The first output pads 210 and the second output pads 220 may be connected to the integrated circuit of the semiconductor chip 200 and may be used to deliver output signals to the integrated circuit of the semiconductor chip 200.

Referring back to FIGS. 1 and 2, the first and second connection pads 310 and 320 may be provided on the first surface 100U of the film substrate 100. The first connection pads 310 may be disposed in the first connection region CR1. The first connection pads 310 may be spaced apart from each other in the second direction D2. The second connection pads 320 may be disposed in the second connection region CR2. The second connection pads 320 may be spaced apart from each other in the second direction D2. The first and second connection pads 310 and 320 may be spaced apart from each other in the first direction 131, with the semiconductor chip 200 interposed therebetween. The first and second connection pads 310 and 320 may be formed of or include at least one of conductive materials.

Referring to FIGS. 1 and 6, the vias 412 and 414 penetrating the film substrate 100 may be provided in the mounting region MR. The vias 412 and 414 may include first vias 412 and second vias 414. The first vias 412 may be spaced apart from the first output pads 210 in the first direction D1. The first vias 412 may be spaced apart from each other in the second direction D2. In an embodiment of the present inventive concept, a distance between the first vi as 412 may be larger than or equal to about 85 μm. The second vias 414 may be spaced apart from the second connection pads 320 in the first direction D1. The second vias 414 may be spaced apart from each other in the second direction D2. Some of the first and second vias 412 and 414 may be provided to penetrate the film substrate 100 and may be exposed to the outside of the film substrate 100. A distance between the second vias 414 may be larger than or equal to about 85 μm. As an example, the vias 412 and 414 may have a diameter of about 23 μm. The vias 412 and 414 may be formed of or include a conductive material. For example, the vias 412 and 414 may be formed of or include copper.

The wires 410, 420, and 450 may be provided on the film substrate 100. The wires 410, 420, and 450 may be disposed on the first surface 100U and/or the second surface 100D of the film substrate 100. The wires 410, 420, and 450 may be formed of or include at least one of conductive materials.

The wires 410, 420, and 450 may include first wires 450, second wires 410, and third wires 420. The first wires 450 may be provided on the first surface 100U of the film substrate 100. The first wires 450 may connect the semiconductor chip 200 to the first connection pads 310. The first wires 450 may connect the input pads 250 to the first connection pads 310. The first wires 450 may be extended from the input pads 250 toward the first connection region CR1 in the first direction D1. The first wires 450 may be spaced apart from each other in the second direction D2. The first wires 450 may be extended to the first connection region CR1 and may be connected to the first connection pads 310 in the first connection region CR1. A distance between the first wires 450 may increase as a distance from the semiconductor chip 200 to the first connection region CR1 decreases. Each of the first wires 450 may connect one of the input pads 250 to a first connection pad 310b, which is a corresponding one of the first connection pads 310. The first connection pad 310b may be electrically connected to the semiconductor chip 200 through a corresponding one of the input pads 250 and a corresponding one of the first wires 450.

Referring to FIGS. 1, 2, and 5, the second wires 410 may connect the semiconductor chip 200 to the second connection pads 320. The second wires 410 may connect the first output pads 210 to the second connection pads 320. The second wires 410 may include first sub-wires 411, second sub-wires 413, and third sub-wires 415. The first sub-wires 411 may be disposed on the first surface 100U of the film substrate 100. The first sub-wires 411 may be extended from the first output pads 210 to the first vias 412 in the first direction D1. The first sub-wires 411 may be spaced apart from each other in the second direction D2. As an example, the first sub-wires 411 may be provided to have a substantially uniform distance therebetween.

The second sub-wires 413 may be disposed on the second surface 100D of the film substrate 100. The second sub-wires 413 may be extended from the first vias 412 to the second vias 414. The second sub-wires 413 may connect the first vias 412 to the second vias 414. The second sub-wires 413 may be spaced apart from each other. As an example, the second sub-wires 413 may be spaced apart from each other by a substantially uniform distance. At least a portion of each of the second sub-wires 413 may be overlapped with the semiconductor chip 200, when viewed in a plan view. For example, at least a portion of each of the second sub-wires 413 may be disposed on a region of the second surface 100D corresponding to the first surface 100U of the film substrate 100, on which the semiconductor chip 200 is mounted. The second sub-wires 413 may be referred to as “lower wires”.

The third sub-wires 415 may be disposed on the first surface 100U of the film substrate 100. The third sub-wires 415 may be extended from the second vias 414 to the second connection pads 320 in the opposite direction of the first direction D1. The third sub-wires 415 may connect the second vias 414 to the second connection pads 320. The third sub-wires 415 may be spaced apart from each other in the second direction D2. As an example, the third sub-wires 415 may be spaced apart from each other by a substantially uniform distance. Each of the second wires 410 may connect one of the first output pads 210 to a second connection pad 320b, which is a corresponding one of the second connection pads 320. The second connection pad 320b may be electrically connected to the semiconductor chip 200 through the corresponding first output pad 210 and the corresponding second wire 410. For example, the second connection pad 320b may be electrically connected to the semiconductor chip 200 through a corresponding one of the first output pads 210, a corresponding one of the first sub-wires 411, a corresponding one of the first vias 412, a corresponding one of the second sub-wires 413, a corresponding one of the second vias 414, and a corresponding one of the third sub-wires 415.

The third wires 420 may be provided on the first surface 100U of the film substrate 100. The first wires 450 may connect the semiconductor chip 200 to the second connection pads 320. The third wires 420 may connect the second output pads 220 to the second connection pads 320. The third wires 420 may be extended from the second output pads 220 to the second connection region CR2 in the opposite direction of, the first direction D1. The third wires 420 may be spaced apart from each other. A distance between the third wires 420 may increase as a distance from the semiconductor chip 200 to the second connection region CR2 decreases. Each of the third wires 420 may connect one of the second output pads 220 to a second connection pad 320c, which is a corresponding one of the second connection pads 320. The second connection pad 320c may be electrically connected to the semiconductor chip 200 through the corresponding second output pad 220 and the corresponding third wire 420.

As shown in FIG. 1, the wires 410, 420, and 450 may include a bent portion. However, the present inventive concept is not limited to this example, and in some embodiments, the positions of the first and second connection pads 310 and 320, the size of the semiconductor chip 200, and the positions of the input pads 250 and the first and second output pads 210 and 220 in the semiconductor chip 200 may be variously changed. A protection layer may be provided on the wires 410, 420, and 450. The protection layer may be configured to cover and protect the wires 410, 420, and 450. The protection layer may be formed of or include an insulating material. For example, the protection layer may be formed of or include at least one of solder resist materials.

The semiconductor package 1 may further include fourth wires 430. The fourth wires 430 may be provided on the first surface 1000 of the film substrate 100. The fourth wires 430 may connect the first connection pads 310 to the second connection pads 320, respectively. The fourth wires 430 may be extended from the second connection pads 320 to the first connection region CR1 in the first direction D1. The fourth wires 430 may be spaced apart from each other. The fourth wires 430 may be extended to the first connection region CR1 and may be connected to the first connection pads 310. Each of the fourth wires 430 may be used to directly connect one (e.g., 310a) of the first connection pads 310 to a corresponding one 320a of the second connection pads 320.

Referring to FIGS. 3 to 5, the semiconductor chip 200 may be mounted on the film substrate 100 and on the first wires 450, the second wires 410, and the third wires 420. For example, when viewed in a plan view, some of the first wires 450, some of the second wires 410, and some of the third wires 420 may be overlapped with the semiconductor chip 200. Such ones of the first, second, and third wires 450, 410, and 420 may be extended to a level below the semiconductor chip 200. For example, the some of the first wires 450 may be vertically overlapped with the input pads 250. In addition, the some of the second wires 410 may be vertically overlapped with the first output pads 210, and the some of the third wires 420 may be vertically overlapped with the second output pads 220. Chip terminals 230 may be provided between the some of the first wires 450 and the input pads 250, between the some of the second wires 410 and the first output pads 210, and between the some of the third wires 420 and the second output pads 220. The semiconductor chip 200 may be electrically connected to the first wires 450, the second wires 410, and the third wires 420 through the chip terminals 230. At least one of the chip terminals 230 may be a solder ball, a solder pillar, and a solder bump. The chip terminals 230 may be formed of or include at least one of metallic materials.

An under fill layer 240 may be provided to fill a gap, which is formed between the film substrate 100 and the semiconductor chip 200. In an embodiment of the present inventive concept, the under fill layer 240 may be provided to hermetically seal the chip terminals 230. The under fill layer 240 may be provided to partially cover the first wires 450, the second wires 410, and the third wires 420. The under fill layer 240 may be formed of or include at least one of insulating polymers (e.g., epoxy-based polymers).

Referring back to FIG. 1, the first connection pads 310 and the first output pads 210 may be spaced apart from each other by a first width W1 in the first direction D1. Each of the output pad regions OP may have a second width W2 in the second direction D2. In an embodiment of the present inventive concept, the first width W1 may be equal to or smaller than the second width W2. Since the first output pads 210 and the second connection pads 320 are connected to each other through the first vias 412, the second vias 414, and the second sub-wires 413 on the second surface 100D of the film substrate 100, the first width W1 may be reduced, compared to the case of connecting the first output pads 210 to the second connection pads 320 through wires on the first surface 100U. For example, the use of the vias 412 and 414 may make it possible to reduce an area of the second wires 410 occupying the first surface 100U of the film substrate 100, when the first output pads 210 near or adjacent to the first connection pads 310 are connected to the second connection pads 320, and thereby to reduce an area of the film substrate 100. As a result, it may be possible to reduce a size of the semiconductor package or to increase an integration density of the semiconductor package.

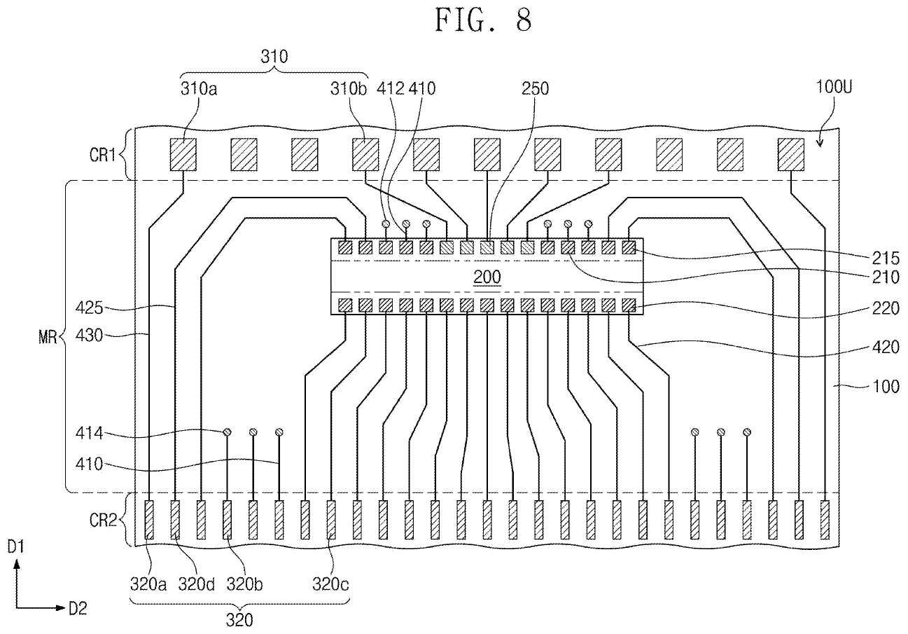

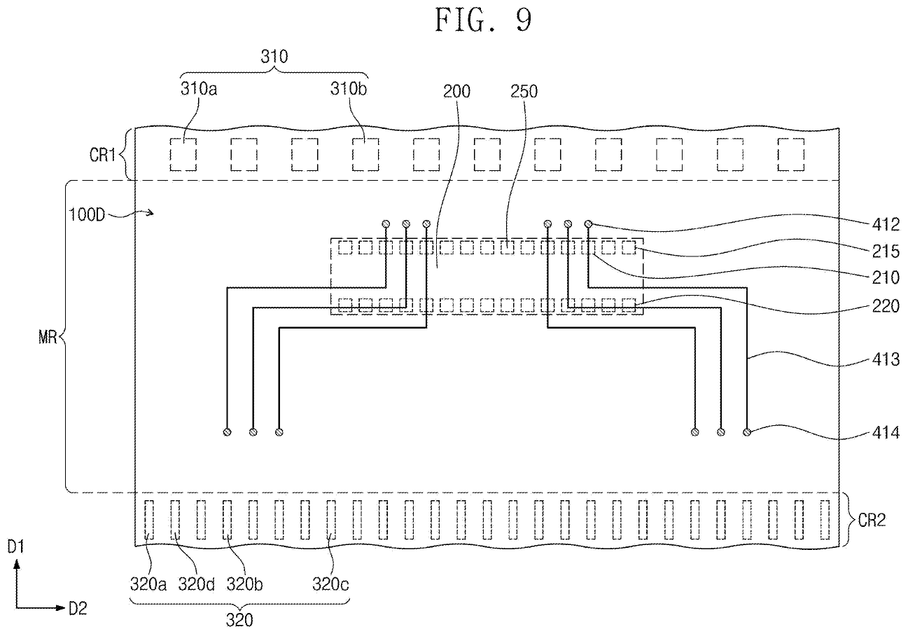

FIG. 8 is a layout diagram illustrating a semiconductor package according to an embodiment of the present inventive concept. FIG. 9 is a layout diagram illustrating a back-side shape of a semiconductor package according to an embodiment of the present inventive concept and, for example, illustrating a bottom surface of the semiconductor package of FIG. 8. For concise description, an element previously described with reference to FIGS. 1 to 7 may be identified by the same reference number without repeating an overlapping description thereof.

Referring to FIGS. 8 and 9, the semiconductor chip 200 may further include third output pads 215. The third output pads 215 may be provided in the output pad regions OP. The third output pads 215 may be spaced apart from the first output pads 210 in the second direction D2. The third output pads 215 may be spaced apart from each other in the second direction D2. The third output pads 215 may be formed of or include a conductive material. The third output pads 215 may be connected to the integrated circuit of the semiconductor chip 200 and may be used to deliver output signals to the integrated circuit of the semiconductor chip 200.

The film substrate 100 may further include fifth wires 425 provided on the first surface 1000 of the film substrate 100. The fifth wires 425 may connect the semiconductor chip 200 to the second connection pads 320. The fifth wires 425 may connect the third output pads 215 to the second connection pads 320. The fifth wires 425 may be extended from the second connection pads 320 in the first direction D1 and may be connected to the third output pads 215. Each of the fifth wires 425 may connect one of the third output pads 215 to a second connection pad 320d, which is a corresponding one of the second connection pads 320. For example, each of the fifth wires 425 may be bent multiple times toward the second connection region CR2. The second connection pad 320d may be electrically connected to the semiconductor chip 200 through the third output pad 215 and the fifth wire 425.

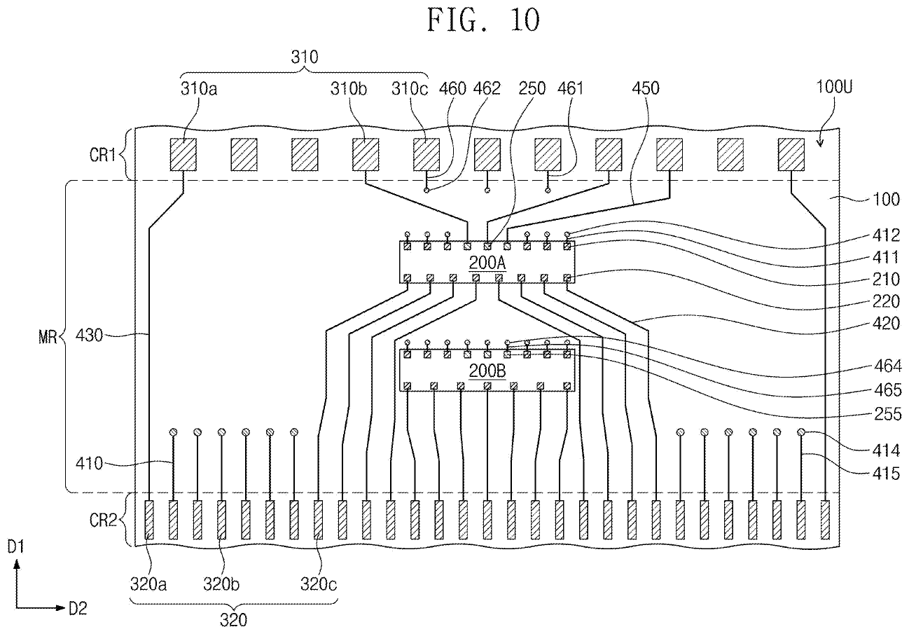

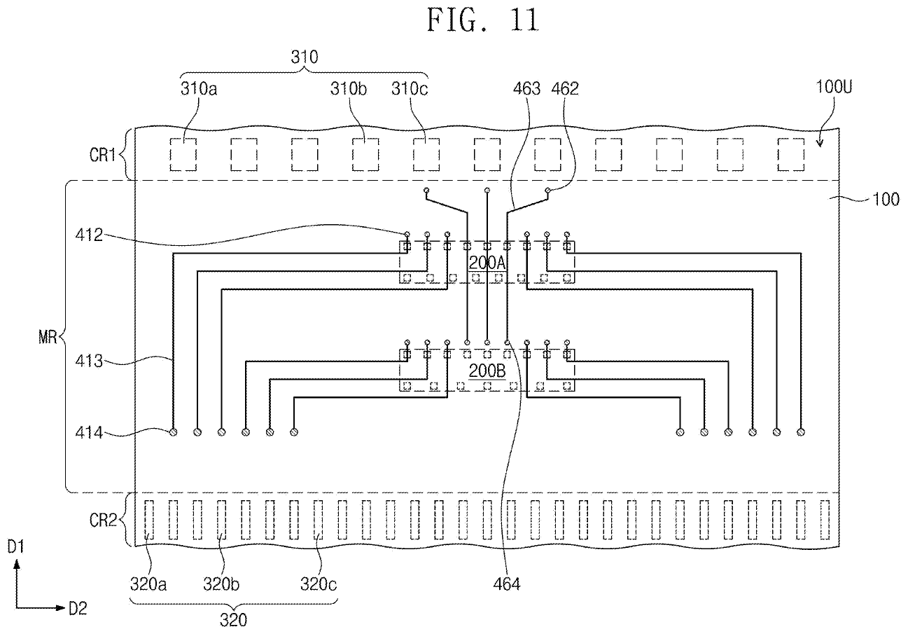

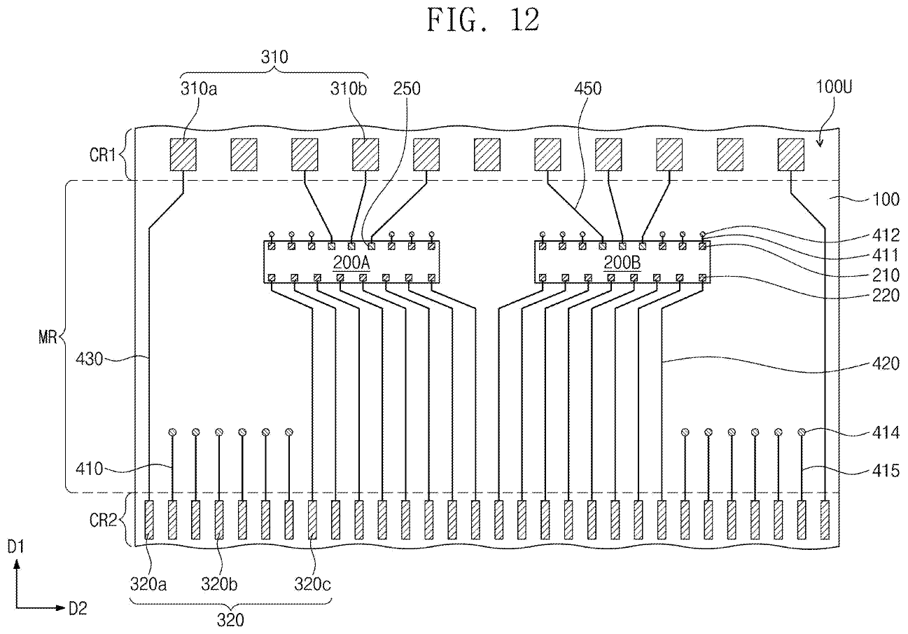

FIG. 10 is a layout diagram illustrating a semiconductor package according to an embodiment of the present inventive concept. FIG. 11 is a layout diagram illustrating a back-side shape of a semiconductor package according to an embodiment of the present inventive concept and, for example, illustrating a bottom surface of the semiconductor package of FIG. 10. For concise description, an element previously described with reference to FIGS. 1 to 7 may be identified by the same reference number without repeating an overlapping description thereof.

Referring to FIGS. 10 and 11, a plurality of semiconductor chips 200 may be provided. The semiconductor chips 200 may include a first semiconductor chip 200A and a second semiconductor chip 200B. The first and second semiconductor chips 200A and 200B may be spaced apart from each other in the first direction D1, on the first surface 100U of the film substrate 100. As an example, the second semiconductor chip 200B may be disposed between the first semiconductor chip 200A and the second connection region CR2. The second semiconductor chip 200B may include second input pads 255. The second input pads 255 may be provided to have substantially the same structure as that of the input pads 250.

The film substrate 100 may further include input wires 460 provided on the film substrate 100. The input wires 460 may connect the semiconductor chip 200 to the first connection pads 310. The input wires 460 may connect the second input pads 255 to the first connection pads 310. Each of the input wires 460 may be provided to connect one of the second input pads 255 to a first connection pad 310c, which is a corresponding one of the first connection pads 310. The film substrate 100 may further include third vias 462 and fourth vias 464, which are provided to penetrate the film substrate 100. The third vias 462 may be spaced apart from the first connection pads 310c in the opposite direction of the first direction D1. As an example, the third vias 462 may be disposed between the first connection pads 310c and the first semiconductor chip 200A. The fourth vi as 464 may be spaced apart from the second input pads 255 in the first direction D1. In an embodiment of the present inventive concept, the fourth vias 464 may be disposed between the first and second semiconductor chips 200A and 200B. In an embodiment of the present inventive concept, the third vias 462 and the fourth vias 464 may be provided to have substantially the same structure as that of the vias 412 and 414.

The input wires 460 may include first input wires 461, second input wires 463, and third input wires 465. The first input wires 461 may be provided on the first surface 100U of the film substrate 100. The first input wires 461 may be extended from the first connection pads 310c in the opposite direction of the first direction D1 and may be connected to the third vias 462. The first input wires 461 may be spaced apart from each other in the second direction D2.

The second input wires 463 may be provided on the second surface 100D of the film substrate 100. The second input wires 463 may be extended from the third vias 462 to the fourth vias 464. The second input wires 463 may connect the third vias 462 to the fourth vias 464. The second input wires 463 may be spaced apart from each other. At least a portion of each of the second input wires 463 may be overlapped with the first semiconductor chip 200A, when viewed in a plan view. The second input wires 463 may be spaced apart from each other.

The third input wires 465 may be disposed on the first surface 100U of the film substrate 100. The third input wires 465 may be extended from the fourth vias 464 in the opposite direction of the first direction D1 and may be connected to the second input pads 255 of the second semiconductor chip 200B. The third input wires 465 may be spaced apart from each other.

One of the first connection pads 310c may be electrically connected to the semiconductor chip 200B through a corresponding one of the first input wires 461, a corresponding one of the third vias 462, a corresponding one of the second input wires 463, a corresponding one of the fourth vias 464, and a corresponding one of the third input wires 465.

The semiconductor chips 200 may further include third output pads, which are connected to the second connection pads 320 through wires provided on the first surface 100U of the film substrate 100.

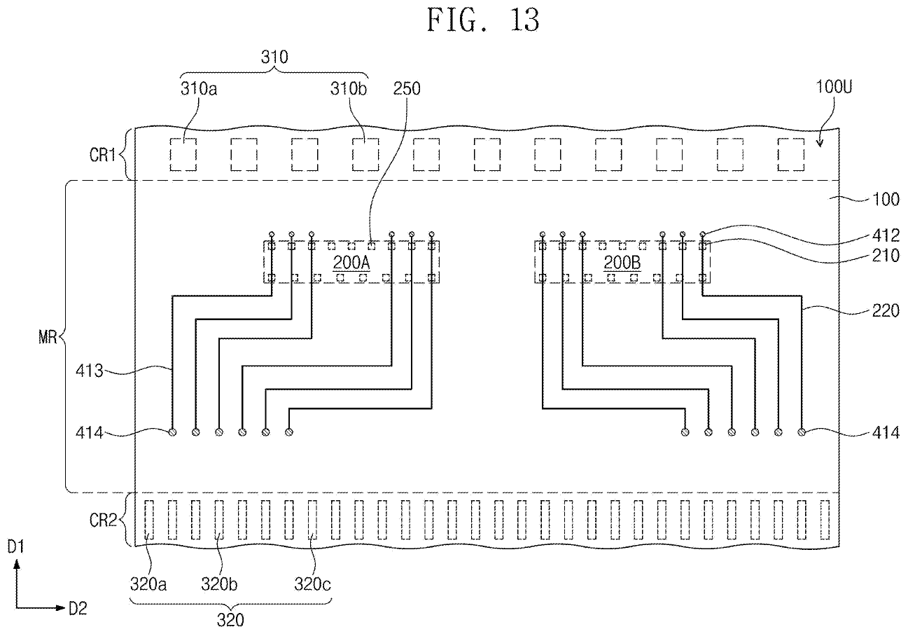

FIG. 12 is a layout diagram illustrating a semiconductor package according to an embodiment of the present inventive concepts. FIG. 13 is a layout diagram illustrating a back-side shape of a semiconductor package according to an embodiment of the present inventive concept and, for example, illustrating a bottom surface of the semiconductor package of FIG. 12. For concise description, an element previously described with reference to FIGS. 1 to 7 may be identified by the same reference number without repeating an overlapping description thereof.

Referring to FIGS. 12 and 13, a plurality of semiconductor chips 200 may be provided. The semiconductor chips 200 may include the first and second semiconductor chips 200A and 200B. The first and second semiconductor chips 200A and 200B may be spaced apart from each other in the second direction D2, on the first surface 100U of the film substrate 100. Each of the first and second semiconductor chips 200A and 200B may be provided to have substantially the same features as that of the semiconductor chip 200 described with reference to FIGS. 1 to 7.

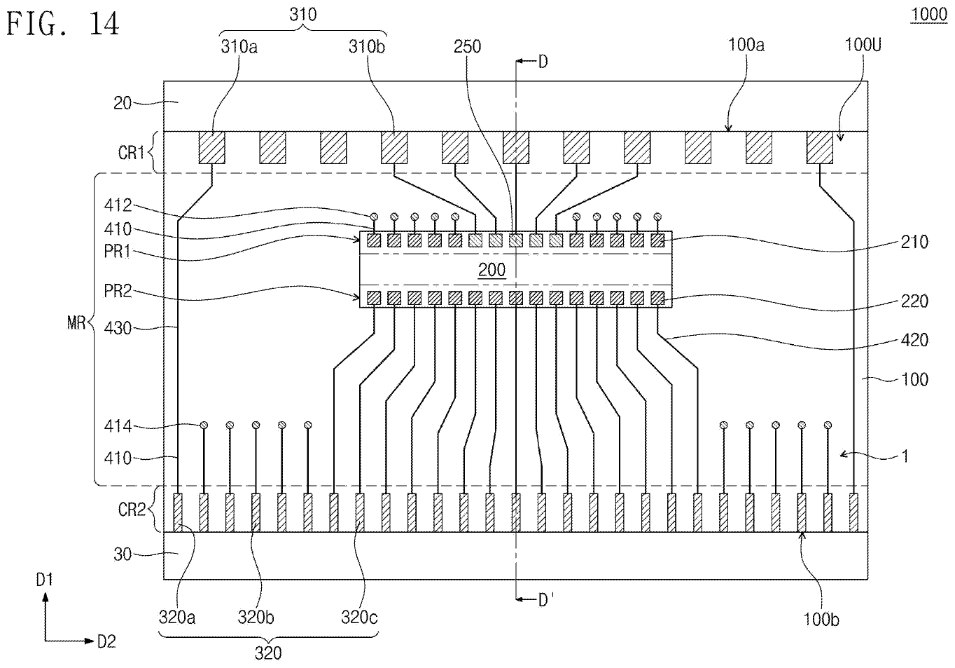

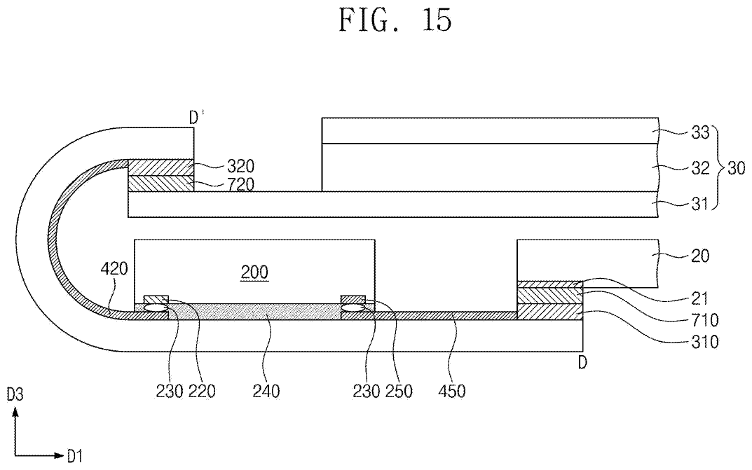

FIG. 14 is a plan view illustrating a package module according to an embodiment of the present inventive concept. FIG. 15 is a sectional view, which is taken along a line D-D′ of FIG. 14 to illustrate a package module according to an embodiment of the present inventive concept.

Referring to FIGS. 14 and 15, a package module 1000 may include a semiconductor package 1, a circuit substrate 20, and a display device 30. The package module 1000 may be a display device assembly. Here, the semiconductor package 1 described with reference to FIGS. 1 to 7 may be used to manufacture the package module 1000. The semiconductor package 1 may be referred to as a film package. Referring back to FIG. 1, the circuit substrate 20 may be mounted on the first end portion 100a of the film substrate 100 of the semiconductor package 1. As shown in FIG. 15, the film substrate 100 may have a flexible property and may be bent. For example, the film substrate 100 may be bent such that a portion of the first surface 100U of the film substrate 100 provided with the semiconductor chip 200 faces another portion of the first surface 100U.

The circuit substrate 20 may be disposed on the first surface 100U of the film substrate 100. The circuit substrate 20 may be adjacent to the first end portion 100a of the film substrate 100. In an embodiment of the present inventive concept, a printed circuit board (PCB) or a flexible printed circuit board (FPCB) may be used as the circuit substrate 20. Furthermore, the protection layer described with reference to FIG. 1 may be provided to expose the first connection pads 310. Input connecting portions 710 may be provided between the first connection pads 310 and pads 21 of the circuit substrate 20. The input connecting portions 710 may include an anisotropic conductive film (ACF). In an embodiment of the present inventive concept, the input connecting portions 710 may include solder balls or solder bumps. As shown in FIG. 15, the circuit substrate 20 may be electrically connected to the first connection pads 310 through the input connecting portions 710. The circuit substrate 20 may be electrically connected to the semiconductor chip 200 through the first connection pads 310 and the first wires 450.

The display device 30 may be disposed on a top surface 100u of the film substrate 100. The display device 30 may be adjacent to the second end portion 100b of the film substrate 100. The display device 30 may include a display substrate 31, a display panel 32, and a protection part 33, which are stacked on each other. Output connecting portions 720 may be provided between the display substrate 31 and the second connection pads 320. The output connecting portions 720 may be an anisotropic conductive film. In an embodiment of the present inventive concept, the output connecting portions 720 may include solder balls or solder bumps. As shown in FIG. 15, the display substrate 31 may be electrically connected to the semiconductor chip 200 through the output connecting portions 720. The display device 30 may be electrically connected to the semiconductor chip 200 through the second connection pads 320, the second wires 410, and the third wires 420.

Signals may be transmitted from the circuit substrate 20 to the semiconductor chip 200 through the first wires 450. The semiconductor chip 200 may include integrated driving circuits a gate driver circuit and/or a data driver circuit) and may be configured to generate driving signals (e.g., gate driving signals and/or data driving signals). The driving signals, which are generated by the semiconductor chip 200, may be applied to gate lines and/or data lines in the display substrate 31 through the second and third wires 410 and 420. The display panel 32 may be driven by the driving signals. In an embodiment of the present inventive concept, the package module 1000 may include a plurality of semiconductor chips 200.

In a semiconductor package according to an embodiment of the present inventive concept, wires may be used to connect output pads of a semiconductor chip to connection pads, which will be connected to a display device, and the wires may be placed on both of top and bottom surfaces of a film substrate. Thus, it may be possible to maintain or reduce a size of the film substrate, even when the number of the output pads of the semiconductor chip is increased. Thus, it may be possible to realize a semiconductor package with a relatively small size and an increased integration density.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A semiconductor package, comprising:
a film having a first surface and a second surface, which are opposite to each other, and comprising a first connection region and a second connection region, which are spaced apart from each other in a first direction;
first connection pads disposed on the first connection region of the film;
second connection pads disposed on the second connection region of the film; and
a semiconductor chip disposed on the first surface of the film and between the first connection region and the second connection region,
wherein the semiconductor chip comprises:
input pads disposed on a first pad region, wherein the first pad region is adjacent to the first connection region;
first output pads disposed on the first pad region; and
second output pads disposed on a second pad region spaced apart from the first pad region, and
at least one of the first output pads is electrically connected to a corresponding second connection pad of the second connection pads through a first via and a second via penetrating the film.

2. The semiconductor package of claim 1, further comprising wires,
wherein the wires comprise:
first wires connecting the input pads to the first connection pads;
second wires connecting the first output pads to the second connection pads; and
third wires connecting the second output pads to the second connection pads,
wherein at least one of the second wires is provided on the second surface of the film to electrically connect the first via to the second via.

3. The semiconductor package of claim 2, wherein the at least one of the second wires comprises:
a first sub-wire connecting the at least one of the first output pads to the first via;
a second sub-wire connecting the first via to the second via; and
a third sub-wire connecting the second via to the corresponding second connection pad,
wherein the first sub-wire and the third sub-wire are disposed on the first surface of the film, and
the second sub-wire is disposed on the second surface of the film.

4. The semiconductor package of claim 1, wherein the first pad region comprises output pad regions and an input pad region,
the output pad regions are disposed at opposing sides of the input pad region,
the first output pads are disposed on the output pad region, and
the input pads are disposed on the input pad region.

5. The semiconductor package of claim 4, wherein the first connection pads and the first output pads are spaced apart from each other by a first width in the first direction,
each of the output pad regions has a second width in a second direction crossing the first direction, and
the first width is smaller than or equal to the second width.

6. The semiconductor package of claim 2, wherein the first wires and the third wires are disposed on the first surface of the film.

7. The semiconductor package of claim 2, wherein the first, second and third wires are provided to electrically connect the semiconductor chip to the first connection pads and to electrically connect the semiconductor chip to the second connection pads.

8. The semiconductor package of claim 2, further comprising at least one fourth wire,
wherein the fourth wire is provided to connect a corresponding one of the first connection pads to a corresponding one of the second connection pads.

9. The semiconductor package of claim 2, wherein at least a portion of each of the first, second, and third wires is overlapped with the semiconductor chip.

10. The semiconductor package of claim 3, wherein at least a portion of the second sub-wire is overlapped with the semiconductor chip.

11. The semiconductor package of claim 1, wherein the first via is disposed between the semiconductor chip and the first connection region, and
the second via is disposed between the semiconductor chip and the second connection region.

12. A semiconductor package, comprising:
a film substrate having a first surface and a second surface, which are opposite to each other, wherein the film substrate comprises first connection pads, which are provided on the first surface and are spaced apart from each other in a first direction, and second connection pads, which are spaced apart from the first connection pads in a second direction crossing the first direction;
a semiconductor chip provided on the first surface and between the first connection pads and the second connection pads;
wires connecting the semiconductor chip to the first connection pads and the second connection pads;
first vias provided between the semiconductor chip and the first connection pads, wherein the first vias penetrate the film substrate; and
second vias provided between the semiconductor chip and the second connection pads, wherein the second vias penetrate the film substrate,
wherein the semiconductor chip and the second connection pads are electrically connected to each other through the first vias and the second vias.

13. The semiconductor package of claim 12, wherein the semiconductor chip comprises:
first output pads provided on a bottom surface of the semiconductor chip and spaced apart from each other in the first direction; and
second output pads provided on the bottom surface of the semiconductor chip and spaced apart from the first output pads in the second direction;
wherein the first output pads are closer to the first connection pads than the second output pads are, and
the first output pads are electrically connected to the second connection pads.

14. The semiconductor package of claim 13, wherein the first output pads are electrically connected to the second connection pads through the first vias and the second vias.

15. The semiconductor package of claim 13, further comprising wires connecting the first output pads to the second connection pads,
wherein the wires comprise:
first sub-wires provided on the first surface of the film substrate to connect the first output pads to the first vias, respectively;
second sub-wires provided on the second surface of the film substrate to connect the first vias to the second vias, respectively; and
third sub-wires provided on the first surface of the film substrate to connect the second vias to the second connection pads, respectively.

16. The semiconductor package of claim 13, wherein the first output pads are provided in a first output pad region and a second output pad region, which are spaced apart from each other on the bottom surface of the semiconductor chip,
the first output pads are spaced apart from the first connection pads by a first width in the second direction,
each of the first and second output pad regions has a second width in the first direction, and
the first width is smaller than or equal to the second width.

17. The semiconductor package of claim 13, wherein the semiconductor chip further comprises input pads provided on the bottom surface thereof, and
the input pads are electrically connected to the first connection pads.

18. A semiconductor module, comprising:
a circuit substrate;
a display device spaced apart from the circuit substrate; and
a film package provided between the circuit substrate and the display device and electrically connected to the circuit substrate and the display device,
wherein the film package comprises:
a film substrate having a first surface and a second surface, which are opposite to each other;
a semiconductor chip mounted on a first surface of the film substrate, wherein the semiconductor chip comprises a first pad region and a second pad region, wherein the first pad region is adjacent to the circuit substrate, and the second pad region is adjacent to the display device;
first connection pads provided on the first surface of the film substrate and between the semiconductor chip and the circuit substrate;
second connection pads provided on the first surface of the film substrate and between the semiconductor chip and the display device;
wires electrically connecting the semiconductor chip to the first connection pads and to the second connection pads;
first vias provided between the semiconductor chip and the first connection pads, wherein the first vias penetrate the film substrate;
second vias provided between the semiconductor chip and the second connection pads, wherein the second vias penetrate the film substrate;
first output pads provided in the first pad region;
second output pads provided in the second pad region; and
lower wires provided on the second surface of the film substrate and connecting the first vias to the second vias,
wherein at least one of the first output pads is electrically connected to a corresponding second connection pad of the second connection pads through a corresponding lower wire of the lower wires.

19. The semiconductor module of claim 18, wherein the semiconductor chip and the circuit substrate are electrically connected to each other through the first connection pads, and
the semiconductor chip and the display device are electrically connected to each other through the second connection pads.

20. The semiconductor module of claim 18, wherein the first pad region comprises output pad regions and an input pad region,
the output pad regions are disposed at opposing sides of the input pad region,
the first output pads are disposed on the output pad region,
the first connection pads and the first output pads are spaced apart from each other by a first width in a first direction,
each of the output pad regions has a second width in a second direction crossing the first direction, and
the first width is smaller than or equal to the second width.
